(19) United States
(12) Patent Application Publication
(10) Pub. No.: US 2009/0078980 A1
(43) Pub. Date: Mar. 26, 2009

(54) Method for Producing an Integrated Circuit, Integrated Circuit, DRAM Device and Memory Module

(76) Inventor: Inho Park, Dresden (DE)

Correspondence Address: SLATER & MATSIL, L.L.P., 17950 PRESTON ROAD, SUITE 1000, DALLAS, TX, 75252, US

(21) Appl. No.: 12/179,227

(22) Filed: Jul. 24, 2008

(30) Foreign Application Priority Data
Sep. 25, 2007 (DE) 10 2007 045 734.2

(51) Int. Cl. H01L 29/94; H01L 21/3205

(52) U.S. Cl. 257/296; 438/589; 257/E21.294; 257/E29.345

(57) ABSTRACT

A method for producing an integrated circuit is disclosed. The integrated circuit includes an insulating material and a semiconducting material adjacent the insulating material. The semiconducting material is partially removed and the surface of the partially removed semiconducting material is treated. The insulating material is partially removed.

This application claims the benefit of priority from German Application No. 10 2007 045 734.2 filed Sep. 25, 2007, which is incorporated herein, in its entirety, by reference.

### BACKGROUND

The explanations below relate to the technical field of semiconductor components, reference being made in particular to a method for patterning an insulating material and a semiconducting material in semiconductor components. In the present context, the term semiconductor components generally denotes integrated circuits or chips and also individual semiconductors such as, e.g., analog or digital circuits or individual semiconductors, and also semiconductor memory components, such as, e.g., function memory components (PLAs, PALs etc.) and table memory components (ROMs or RAMs, in particular SRAMs and DRAMs).

Alongside other applications such as in micromechanical components or in the patterning of an oxide mask layer, for example, the patterning method can be used for producing a transistor provided with a recess (recessed gate transistor). The transistor type known as the recessed gate transistor involves forming the gate electrode in a recess in order to increase the effective channel length; a three-dimensional semiconductor component having a three-dimensional channel region arises.

The recess of a recessed gate transistor is implemented in parts of the silicon substrate. These parts typically have to be removed selectively with respect to the material of the surrounding insulation. In order to optimize the semiconductor component, the adjacent insulation material is partially removed after the recess has been formed. In this case, the process for the remaining insulation material should ensure that the material has low surface roughness and is patterned uniformly, particularly if the insulation material comprises a system of a plurality of materials.

Various methods can be used for the partial removal of the adjacent insulation material. On the one hand, it is possible to employ a so-called wet etching method. In this case, the insulation material is removed by means of a liquid etchant. In the case of removal by a “dry thermal surface reaction” method, the insulation material is removed by means of a surface reaction.

### BRIEF DESCRIPTION OF THE DRAWINGS

The invention is explained in more detail below on the basis of preferred exemplary embodiments in conjunction with the accompanying drawings. With respect to the figures:

FIG. 1a shows a schematic illustration of an insulating material and a semiconducting material, the insulating material and the semiconducting material being adjacent;

FIG. 1b shows a schematic illustration of an arrangement comprising an insulating material and a semiconducting material after the partial removal of the semiconducting material;

FIG. 1c shows a schematic illustration of an arrangement comprising an insulating material and a semiconducting material after the surface treatment of the partially removed semiconducting material;

FIG. 1d shows a schematic illustration of an arrangement comprising an insulating material and a semiconducting material after the partial removal of the insulating material;

FIG. 2a shows a schematic illustration of two insulating materials and a semiconducting material, the insulating materials and the semiconducting material being adjacent;

FIG. 2b shows a schematic illustration of an arrangement comprising two insulating materials and a semiconducting material after the partial removal of the semiconducting material;

FIG. 2c shows a schematic illustration of an arrangement comprising two insulating materials and a semiconducting material after the surface treatment of the partially removed semiconducting material;

FIG. 2d shows a schematic illustration of an arrangement comprising two insulating materials and a semiconducting material after the partial removal of the insulating materials;

FIG. 3 shows a schematic illustration of an insulating material and a semiconducting material, the insulating material and the semiconducting material being adjacent and being separated from one another by a material;

FIG. 4 shows a schematic illustration of an insulating material and a semiconducting material, the insulating material and the semiconducting material being adjacent and being separated from one another by a gap; and

FIG. 5 schematically shows a method for producing an integrated circuit, comprising the patterning of an insulating material and a semiconducting material, the insulating material and the semiconducting material being adjacent.

### DETAILED DESCRIPTION OF ILLUSTRATIVE EMBODIMENTS

In one aspect, the invention provides a method for patterning an insulating material and a semiconducting material, the insulating material and the semiconducting material being adjacent. The patterning method can be used, for example, for producing a transistor provided with a recess (recessed gate transistor).

As it will be described in detail below a first embodiment provides a method for producing an integrated circuit. The integrated circuit includes insulating material and semiconducting material, the insulating material and the semiconducting material being placed adjacent one another. In the method, the semiconducting material is partially removed. The surface of the partially removed semiconducting material is treated, and the insulating material is partially removed.

The insulating material and the semiconducting material are placed adjacent to one another. This should be understood to mean that they can directly adjoin one another and be in contact with one another, or that they can be separated from one another by a material. It should also be understood to mean that the insulating material and the semiconducting material can be separated by a gap.

The removal of the semiconducting material can take place anisotropically, for example. The surface treatment of the semiconducting material can comprise the deposition or formation of a protective layer on the semiconducting material. The removal of the insulating material can take place isotropically.

The partial removal of the semiconducting material, the surface treatment of the semiconducting material and the partial removal of the insulating material can be performed, for example, in at least one process chamber. The process chamber can contain a source for generating a plasma. The coupling of power into the plasma can be performed inductively. The pressure in the process chamber can be lower than 10 mtorr (1.3 Pa).

Process chamber is understood here to mean an individual chamber for processing wafers (e.g., bulk silicon or SOI). It can likewise be taken to mean a plurality of individual chambers which are connected to one another via a lock device and between which the wafers can be transferred without ventilation of the chambers or lock device.

One or more process gases from the group HBr, HeO₂ and SF₆ can be selected for the partial removal of the semiconducting material by means of a plasma. A nitrogen-containing process gas, e.g., N₂, can be selected for the surface treatment of the semiconducting material. One or more process gases from the group CHF₃ and HeO₂ can be selected for the partial removal of the insulating material.

The semiconducting material can comprise polycrystalline silicon or crystalline silicon. The insulating material can be selected from the group HDP silicon oxide, SOD dielectric, or SOD silicon oxide.

In this case, HDP silicon oxide means that the silicon oxide is deposited by means of a plasma process with a high plasma density (high density plasma). SOD dielectric means that the dielectric is applied by means of a spin-on operation (spin-on dielectric). The term SOD silicon oxide should likewise be understood to mean: silicon oxide applied by means of a spin-on operation.

The insulating material can likewise comprise two insulating materials. The insulating materials can be different and can be selected from the group of HDP silicon oxide, SOD dielectric, or SOD silicon oxide, as examples.

What is furthermore described is an integrated circuit that includes an insulating material and a semiconducting material. The insulating material and the semiconducting material are adjacent one another and have been patterned by means of the following steps: partially removing of the semiconducting material; treating the surface of the partially removed semiconducting material; and partially removing of the insulating material.

A DRAM is also described. The DRAM device contains an integrated circuit comprising an insulating material and a semiconducting material. The insulating material and the semiconducting material are adjacent and have been patterned by means of the following steps: partially removing of the semiconducting material; treating the surface of the partially removed semiconducting material; and partially removing of the insulating material.

The DRAM device can be such that it is stackable.

What is furthermore described is a memory module containing an integrated circuit comprising an insulating material and a semiconducting material. The insulating material and the semiconducting material are adjacent and have been patterned by means of the following steps: partially removing of the semiconducting material; treating the surface of the partially removed semiconducting material; and partially removing of the insulating material.

Embodiments of the invention will now be described in more detail below with reference to the associated drawings. The drawings show preferred embodiments of the invention. The invention can be realized in various embodiments and there is no intention to restrict the invention to the embodiments illustrated here. Rather, these embodiments serve to carefully and completely fashion the disclosure and to make the scope of the invention fully accessible to those skilled in the art. The drawings are not to scale but rather are intended to schematically illustrate what is essential for an understanding of the invention. Layer thicknesses and layer widths are not to scale.

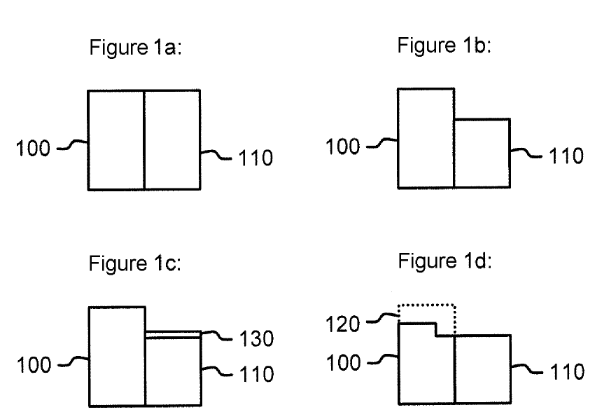

FIGS. 1a to 1d show by way of example the inventive method for producing an integrated circuit.

FIG. 1a illustrates the arrangement of an insulating material (100) and a semiconducting material (110), the two materials being arranged adjacent to one another. This should be understood to mean that they can directly adjoin one another and be in contact with one another, or that they can be separated from one another by a material. It should also be understood to mean that the insulating material (100) and the semiconducting material (110) can be separated by a gap.

FIG. 1b shows the arrangement comprising insulating material (100) and semiconducting material (110) after a first method step has been performed. The semiconducting material (110) was partially removed. This can take place by means of an anisotropic removal method. The removal of the semiconducting material (110) is intended to be performed selectively with respect to the insulating material (100), that is to say that the removal rate of the removal method with respect to the semiconducting material (110) is greater than that with respect to the insulating material (100).

The partial removal of the semiconducting material (110) can be carried out in a process chamber containing a source for generating a plasma. The coupling of power into the plasma can be performed inductively. The pressure in the process chamber can be lower than 10 mtorr (1.3 Pa).

For the partial removal of the semiconducting material (110) in the process chamber, gases from the group of HBr, HeO₂ and SF₆ can be selected, for example, as one or more process gases.

The semiconducting material (110) can comprise polycrystalline or crystalline silicon.

FIG. 1c shows the arrangement comprising insulating material (100) and semiconducting material (110) after a further method step has been performed. After the surface treatment of the partially removed semiconducting material (110), the semiconducting material (110) has been covered with a protective layer (130). In this method step, a material was deposited as protective layer (130). A protective layer (130) can likewise have been formed by means of surface reactions as a result of the surface treatment. By way of example, a process gas can react with the surface of the semiconducting material (110) and form a protective layer (130).

The surface treatment of the partially removed semiconducting material (110) can be carried out in a process chamber containing a source for generating a plasma. The coupling of power into the plasma can be performed inductively. The pressure in the process chamber can be lower than 10 mtorr (1.3 Pa).

By way of example, a nitrogen-containing process gas, e.g., N₂, can be selected for the surface treatment of the partially removed semiconducting material (110) in a process chamber containing a source for generating a plasma.

FIG. 1d shows the arrangement comprising insulating material (100) and semiconducting material (110) after a further method step has been performed. This can take place using an isotropic removal method. During the partial removal of the insulating material (100), the protective layer (130) on the partially removed semiconducting material (110) can likewise be partially or completely removed. The removal of the insulating material (100) is intended to be performed selectively with respect to the semiconducting material (110), that is to say that the removal rate of the removal method with respect to the insulating material (100) is very much greater than that with respect to the semiconducting material (110). This selectivity can be increased by means of a protective layer (130).

The partial removal of the insulating material (100) can be carried out in a process chamber containing a source for generating a plasma. The coupling of power into the plasma can be performed inductively. The pressure in the process chamber can be lower than 10 mtorr (1.3 Pa).

For the partial removal of the insulating material (100) in a process chamber containing a source for generating a plasma, gases from the group of CHF₃ and HeO₂ can be selected, for example, as one or more process gases.

The insulating material (100) can be selected, for example, from the group HDP silicon oxide, SOD dielectric or SOD silicon oxide.

In this case, HDP silicon oxide means that the silicon oxide is deposited by means of a plasma process with a high plasma density (High Density Plasma). SOD dielectric means that the dielectric is applied by means of a spin-on operation (Spin-On Dielectric). The term SOD silicon oxide should likewise be understood to mean: silicon oxide is applied by means of a spin-on operation.

FIG. 1d includes the formation of the insulating material (100) before the partial removal (120). The isotropic character of the process for removing the insulating material (100) can be discerned in this exemplary embodiment.

The process chamber is understood here to mean an individual chamber for processing wafers (e.g., silicon or SOI). It can likewise be taken to mean a plurality of individual chambers which are connected to one another via a lock device and between which the wafers can be transferred without ventilation of the chambers or lock device.

The method described by way of example in FIGS. 1a to 1d can be performed in a single process chamber. This would reduce the loss of time resulting from lock transfer of the wafers due to path times, evacuation, ventilation, etc.

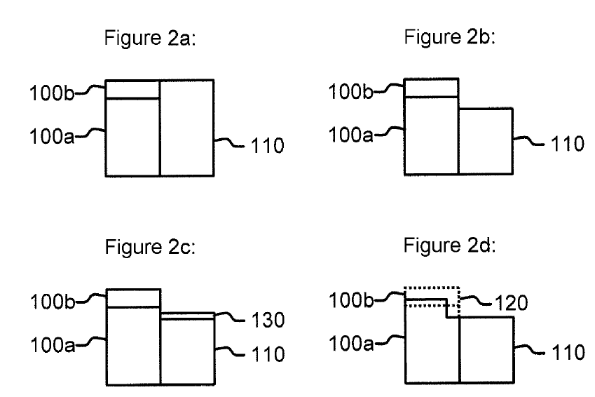

FIGS. 2a to 2d show by way of example the inventive method for producing an integrated circuit. In comparison with FIGS. 1a to 1d, the insulating material (100) comprises two insulating materials (100a, 100b). The insulating materials (100a, 100b) can be selected from the group HDP silicon oxide, SOD dielectric or SOD silicon oxide. The insulating materials (100a, 100b) can be different. As illustrated in FIG. 2d, the rates of removal of the insulating materials (100a, 100b) can be virtually identical. A ratio of the rates of removal of insulating material (100b) with respect to insulating material (100a) of between approximately 2:1 and approximately 1:2 would likewise be possible.

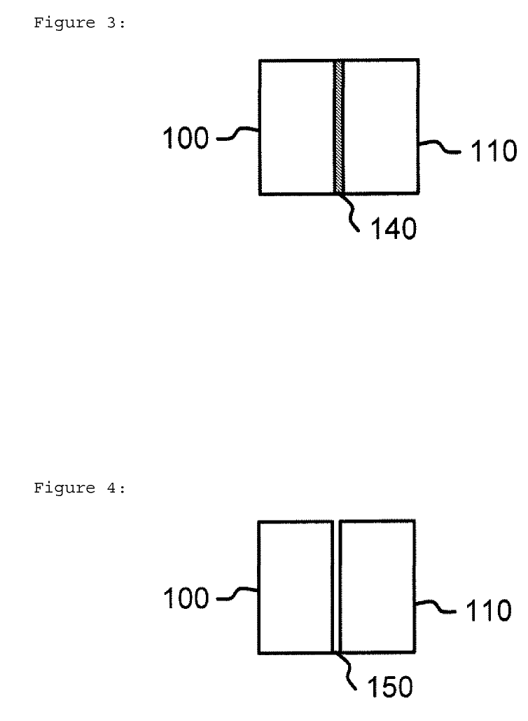

FIG. 3 shows the insulating material (100) and the semiconducting material (110), the two materials being adjacent. A further material (140) is situated between the insulating material (100) and the semiconducting material (110). The further material spaces apart the materials (100) and (110) to be patterned. Material (140) can be formed with a thickness of less than 10 nm. Material (140) can likewise be an insulating material.

FIG. 4 shows the insulating material (100) and the semiconducting material (110), the two materials being adjacent. A gap (150) is situated between the insulating material (100) and the semiconducting material (110). The gap (150) spaces apart the materials (100) and (110) to be patterned. The gap (150) can have a thickness of less than 10 nm.

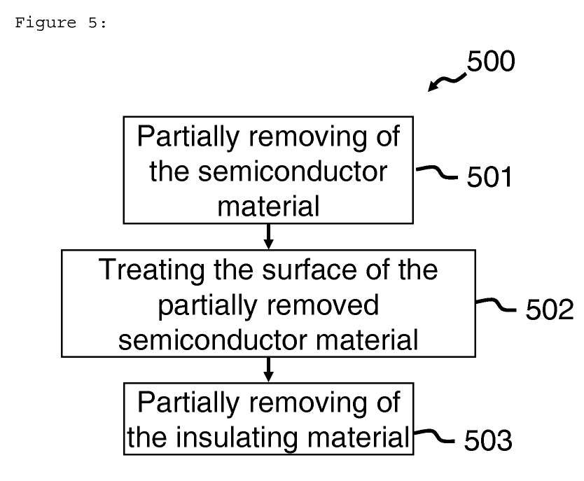

FIG. 5 schematically illustrates a method (500) for producing an integrated circuit, comprising the patterning of an insulating material (100) and a semiconducting material (110), the insulating material (100) and the semiconducting material (110) being adjacent.

Method step (501) for producing an integrated circuit involves the partial removal of a semiconducting material (110). Method step (502) involves the surface treatment of a partially removed semiconducting material (110). Method step (503) involves the partial removal of an insulating material (100).

The inventive method can be used for producing a transistor provided with a recess. In this case, the semiconducting material (110) is crystalline silicon surrounded by insulating material (100). The insulating material (100) can be divided into two materials (100a, 100b) analogously to FIGS. 2a to 2d. In this case, the insulating material (100a) can be an SOD silicon oxide and the insulating material (100b) can be an HDP silicon oxide.

The inventive method can be carried out in a single process chamber with a source for generating a plasma. In this case, the process chamber can be particularly suitable for etching silicon. The coupling of power into the plasma can be performed inductively.

A standard process with the process gases HBr, HeO₂ and SF₆ is used for the partial removal of the crystalline silicon. In this case, the crystalline silicon is etched back selectively with respect to the oxide.

In the same process chamber, in a further method step, an energetic N₂ plasma is used for the surface treatment of the crystalline silicon. In this case, an SiNx surface layer arises on the crystalline silicon.

In the same process chamber, the oxide insulation is etched back isotropically in a further method step. For this purpose, a mixture of CHF₃ and HeO₂ is used as process gases. The pressure in the process chamber is less than 10 mtorr, or between 4 mtorr and 6 mtorr. A high selectivity results on account of the SiNx surface layer on the crystalline silicon. The oxide insulation is opened out laterally with almost no removal of the crystalline silicon.

What is claimed is:

1. A method for producing an integrated circuit, the integrated circuit comprising an insulating material and a semiconducting material adjacent the insulating material, the method comprising:
partially removing the semiconducting material;
treating the surface of the partially removed semiconducting material; and
partially removing the insulating material.

2. The method according to claim 1, wherein removing the semiconducting material comprises anisotropically removing the semiconducting material.

3. The method according to claim 1, wherein treating the surface of the semiconducting material comprises depositing a protective layer on the semiconducting material.

4. The method according to claim 1, wherein removing the insulating material comprises isotropically removing the insulating layer.

5. The method according to claim 1, wherein partially removing the semiconducting material, treating the surface of the semiconducting material and partially removing the insulating material are performed in a single process chamber.

6. The method according to claim 5, wherein the process chamber contains a source for generating a plasma.

7. The method according to claim 6, wherein power is coupled into the plasma inductively.

8. The method according to claim 6, wherein the process chamber operates at a pressure that is lower than 1.3 Pa.

9. The method according to claim 6, wherein one or more process gases from the group HBr, HeO₂ and SF₆ are used for partially removing the semiconducting material.

10. The method according to claim 6, wherein a nitrogen-containing process gas is used for treating the surface of the semiconducting material.

11. The method according to claim 6, wherein one or more process gases from the group CHF₃ and HeO₂ are used for partially removing the insulating material.

12. The method according to claim 1, wherein the semiconducting material comprises polycrystalline silicon or crystalline silicon.

13. The method according to claim 1, wherein the insulating material comprises HDP silicon oxide, SOD dielectric, or SOD silicon oxide.

14. The method according to claim 1, wherein the insulating material comprises two insulating materials.

15. The method according to claim 14, wherein the two insulating materials are different.

16. An integrated circuit comprising an insulating material and a semiconducting material adjacent to the insulating material and the semiconducting material having been patterned by:
partially removing the semiconducting material;
treating the surface of the partially removed semiconducting material; and
partially removing the insulating material.

17. A memory module containing an integrated circuit of claim 16.

18. A DRAM device containing an integrated circuit comprising an insulating material and a semiconducting material adjacent the insulating material, the insulating material and the semiconducting material having been patterned by:
partially removing the semiconducting material;
treating the surface of the partially removed semiconducting material; and
partially removing the insulating material.

19. The DRAM device according to claim 18, which is stackable.
